(19) United States
(12) Patent Application Publication
(10) Pub. No.: US 2013/0160665 A1
(43) Pub. Date: Jun. 27, 2013

(54) PLATE FOR PRODUCING STEREOTYPE AND METHOD FOR PRODUCING SAID PLATE FOR PRODUCING STEREOTYPE

(71) Applicant: Giuseppe Marinelli, Milano (IT)

(72) Inventor: Giuseppe Marinelli, Milano (IT)

(73) Assignee: CIEMMEZETA S.R.L., Monza (IT)

(21) Appl. No.: 13/704,472

(22) PCT Filed: Jun. 17, 2011
(86) PCT No.: PCT/IB11/01380

§ 371 Date: Feb. 27, 2013

(30) Foreign Application Priority Data
Jun. 17, 2010 (IT) MI2010A001097

(51) Int. Cl. B41N 1/00; G03F 7/20

(52) U.S. Cl. CPC B41N 1/00; G03F 7/20
USPC 101/395; 430/300; 430/301

(57) ABSTRACT

A plate for producing printer stereotype is provided with a first layer including a first photopolymerisable polymer and with a second layer including a second photopolymerisable polymer. The first photopolymerisable polymer and the second photopolymerisable polymer have a preferably different Shore A hardness degree.

### TECHNICAL FIELD

The present invention relates to a plate for producing printer stereotype and a method for producing said plate for producing printer stereotypes.

### BACKGROUND ART

The printer stereotypes of a known type comprise a plate provided with a face on which are obtained lettertypes and figures to be printed and a face apt for being coupled to a support element.

Generally, the lettertypes and the figures of stereotypes are obtained by way of UV radiation of the plate, which is made of a photopolymerisable polymer.

In particular, the lettertypes and forms of the stereotype are obtained by interposing between the plate and a UV source a film with some UV-transparent portions, corresponding to the forms of lettertypes and figures of the stereotype.

The radiation of the plate causes the polymerization of only portions of the plate underlying the UV-transparent areas of the film.

Generally, the plate is obtained by a flow of liquid photopolymerisable polymer in a space bounded by containing dams.

Alternatively, the plate is a plate of a solid state photopolymerisable polymer of a predefined thickness.

The plates for producing stereotypes of this type do not guarantee, however, an optimum print quality.

Moreover, in the case of the plate obtained from liquid polymer, the characteristics of the plate also depend on the accuracy and precision adopted by the maker, which is usually a worker of a print shop that produces an instant stereotype or a producer of printer stereotypes.

### DISCLOSURE OF INVENTION

It is therefore an aim of the present invention to produce a plate for producing stereotypes that is free of the disadvantages of the aforementioned prior art; in particular, it is an aim of the invention to produce a plate for producing stereotypes that can optimize print quality.

According to these aims, the present invention relates to a plate for producing printer stereotypes including:
a first layer comprising a first photopolymerisable polymer, and
a second layer comprising a second photopolymerisable polymer.

A further aim of the present invention is to provide a method for producing a plate for producing printer stereotypes adapted for optimizing print quality.

According to these aims, the present invention relates to a method for producing a plate for producing printer stereotypes wherein the plate is produced with a first layer comprising a first photopolymerisable polymer and a second layer comprising a second photopolymerisable polymer.

### BRIEF DESCRIPTION OF THE DRAWINGS

Additional features and advantages of the present invention will appear clear from the following description of a non-limiting embodiment example referring to the figures of the annexed drawings, wherein:

FIG. 1 is a sectional side view of a plate for producing stereotype according to a first embodiment;

FIG. 2 is a perspective schematic view of a method step for producing the plate for producing stereotype of FIG. 1;

FIG. 3 is a sectional side view of a plate for producing stereotype according to a second embodiment.

### BEST MODE FOR CARRYING OUT THE INVENTION

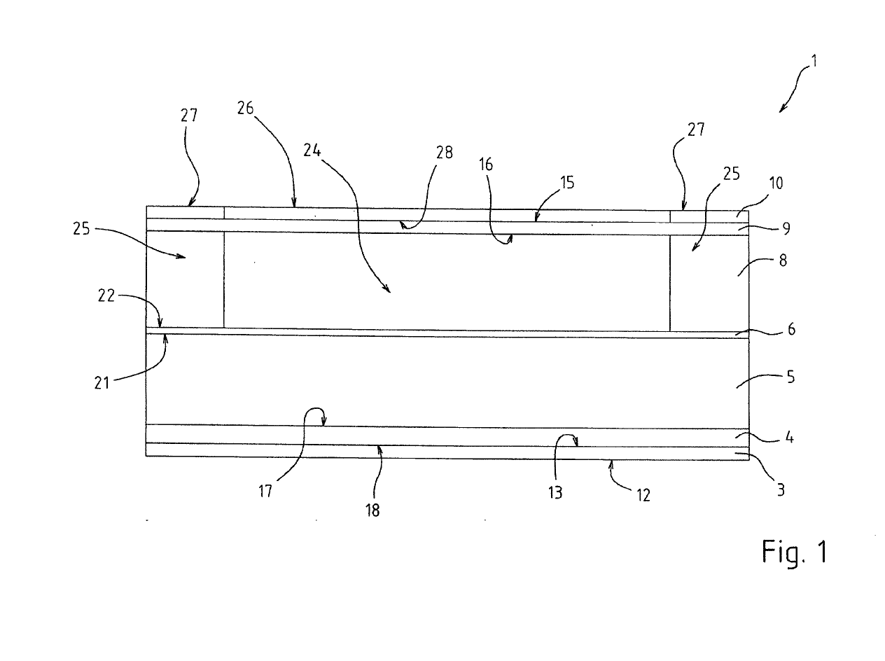

In FIG. 1 indicated with reference number 1 is a plate for producing printer stereotypes.

The plate 1 comprises in sequence a protective outer layer 3, a base layer 4, a first layer 5 comprising a first photopolymerisable polymer, a stiffening layer 6, a second layer 8 comprising a second photopolymerisable polymer, a protective outer layer 9 and a protective film 10.

The outer protective layers 3 and 9 are UV-transparent, are removable and adapted for protecting the plate 1 until lettertypes and forms are obtained on the plate 1 arriving at a stereotype ready for printing.

The protective outer layer 3 has an outer face 12 and an inner face 13. The inner face 13 is treated with silicone and is arranged in contact with the base layer 4. Preferably, the protective outer layer 3 is made of polyethylene terephthalate (PET) and has a thickness of about 36 microns.

The protective outer layer 9 has an outer face 15 and an inner face 16. The outer surface 15 is treated with silicone, while the inner face 16 is arranged in contact with the second layer 8.

Preferably, the protective outer layer is made of polyethylene terephthalate 9 (PET) and has a thickness of about 36 microns. The faces 13 and 15 are treated with silicone for easy removal of respectively the protective outer layer 3 and the protective film 10 as will be later described in detail.

The base layer 4 is preferably made of polyethylene terephthalate (PET) and has a thickness of about 36 microns. In particular, the base layer 4 has a face 17 treated with a primer and a face covered with an adhesive 18. The face 17 is treated with a primer, such as vinyl-type, facilitating the adhesion of the first photopolymerisable polymer either in a liquid state or solid state.

The face 18 is, instead, treated with an adhesive material creating a self-adhesive surface after removing the protective outer layer 3. After the removal of the protective outer layer 3, in fact, the face 18 will be a self-adhesive surface adapted for permitting easy mounting of the stereotype on a support element (such as a roller or a handle of a stamp).

The first layer 5 comprises a first photopolymerisable polymer, which has, after solidification by exposure to UV rays, a Shore A hardness degree between about 20 and about 100, preferably between about 30 and about 55.

The thickness of the first layer 5 is variable between 0.5 mm and 3 mm.

The hardness of the first photopolymerisable polymer and the thickness of the first layer 5 are determined by the type of printing to which the stereotype is destined.

The first photopolymerisable polymer is preferably a polyurethane-based polymer, such as a polymer of the type Exell CS5 or CS9 or VR28 by the DRAMAR company.

The stiffening layer 6 is made of UV-proof material.

In particular, the stiffening layer 6 is preferably made of plastic material (such as a polyester polymer or a polypropylene polymer or a vinyl polymer).

The stiffening layer 6 has two faces 21 and 22, preferably treated with a primer, such as a vinyl-type, so as to ensure proper adhesion of the first photopolymerisable polymer to the face 21 and of the second photopolymerisable polymer to the face 22. In particular, the primer should ensure proper adhesion of the first and second photopolymerisable polymer to respective faces 21 and 22 either before or after the solidification of polymers from UV exposure.

The stiffening layer 6 also contributes to confer particular mechanical properties to the stereotype obtained from the plate 1, as it ensures dimensional stability especially when the stereotype obtained from the plate 1 is coupled to print rollers or when the thickness of the stereotype is particularly high (e.g., in the case of flexographic printing).

A first variant of the present invention, not shown, provides that the stiffening layer 6 is made of UV-transparent material, for example a fabric (a fiberglass, cotton or polyester fabric).

A second variant, not shown in the attached figures provides that the stiffening layer 6 comprises decorative elements (trademarks, logos, etc.) to characterize the plate 1. The first and second layer 5 and 8, in fact, are generally transparent and therefore, the decorations on the stiffening layer 6 are visible from the outside.

The second layer 8 comprises a second photopolymerisable polymer which has, after solidification by exposure to UV rays, a Shore A hardness degree between about 20 and about 100, preferably between about 30 and about 65.

The second photopolymerisable polymer is preferably a polyurethane-based polymer, such as a polymer of the type Exell CS5 or CS9 or VR28 by the DRAMAR company.

The thickness of the second layer 8 is variable between 0.5 mm and 3 mm, preferably.

The hardness of the second photopolymerisable polymer and the thickness of the second layer 8 are determined by the type of printing to which the stereotype is destined.

In particular, the second layer 8 comprises at least a non-polymerized portion 24, in which the photopolymerisable polymer is in a liquid state, surrounded by a polymerized frame 25, in which the photopolymerisable polymer is in a solid (polymerized) state.

The non-polymerized portion 24 in a liquid state is protected by the protective outer layer 9.

In addition, the non-polymerized portion 24 is protected from UV-rays by way of the protective film 10, which presents a UV-proof portion 26 to preserve in a liquid state the non-polymerized portion 24 and a UV-transparent frame 27.

In particular, the protective film 10 has an adhesive face 28, which is adapted for being placed in contact with the outer protective layer 9.

The portion 26 of the protective film 10 is made of UV-proof material, such as a adiactinic film or a paper film.

The non-polymerized portion 24 is adapted for being polymerized in the final production step of the stereotype, which is destined to the formation of lettertypes and forms of the stereotype. Shortly before the formation of lettertypes, the protective film 10 is removed to make impressionable the non-polymerized portion 24.

The removal of the protective layer 10 can be made by the user (for example by the print shop worker) just before the formation process of the lettertypes and figures (production of the stereotype itself).

A variant of the present invention not shown provides that the protective film 10 is removed by the producer of the plate 1 and the protection of the non-polymerized portion 24 of the plate 1 from UV-rays is destined to an appropriate package.

Usually the final step for forming the lettertypes and the forms is carried out at the local print shop where the stereotype is tailored to the needs of the final customer, while the operations of producing the plate 1 can be performed on a large scale at an industrial level. It is understood that the final formation step of the lettertypes and forms of the stereotype can be done at an industrial level.

The Shore A hardness degree of the first photopolymerisable polymer and the Shore A hardness degree of the second photopolymerisable polymer are preferably different.

In particular, the hardness degree of the first and second photopolymerisable polymer depends substantially on the type of printing to which the stereotype is destined.

For example, for printing on a rough and absorbent support, the first photopolymerisable polymer has a Shore A hardness degree greater than the Shore A hardness degree of the second photopolymerisable polymer. For example, the first photopolymerisable polymer has a Shore A hardness degree of about 50, while the Shore A hardness degree of the second photopolymerisable polymer is about 30.

For printing on a smooth and very absorbent surface, however, the first photopolymerisable polymer has a Shore A hardness degree less than the Shore A hardness degree of the second photopolymerisable polymer. For example, the first photopolymerisable polymer has a Shore A hardness degree of about 35, while the Shore A hardness degree of the second photopolymerisable polymer is about 65.

In this way, the second photopolymerisable polymer in fact, will have a greater Shore A hardness degree to ensure greater lettertype accuracy in the stamp, while the first photopolymerisable polymer will have a lesser hardness to adapt better to different support elements to which it is coupled (e.g. a roller) and mitigate and compensate for thickness variations of the lettertypes or the surface on which printing occurs.

Preferably, the first and second photopolymerisable polymer have a different color depending on the Shore A hardness degree. In this way, the choice of the photopolymerisable polymer having appropriate characteristics for a type of printing is fast and simple.

A first variant of the present invention, not shown, provides that the second layer presents a plurality of non-polymerised portions of a rectangular shape, each of which is surrounded by a polymerized frame. In this way, the plate substantially comprises a plurality of plates usable for producing respective independent stereotypes.

A second variant of the present invention, not shown, provides that the protective film 10 is provided along the UV-transparent frame 27 of non UV-transparent portions. In particular, said non UV-transparent portions are configured to generate, during the polymerization of the second photopolymerisable polymer, writings (brands, logos), or small figures carved into the frame to customize the plate for producing stereotypes. The non-polymerised polymer below said portions of the frame 27 is removed during the final washing that is carried out for all the stereotypes.

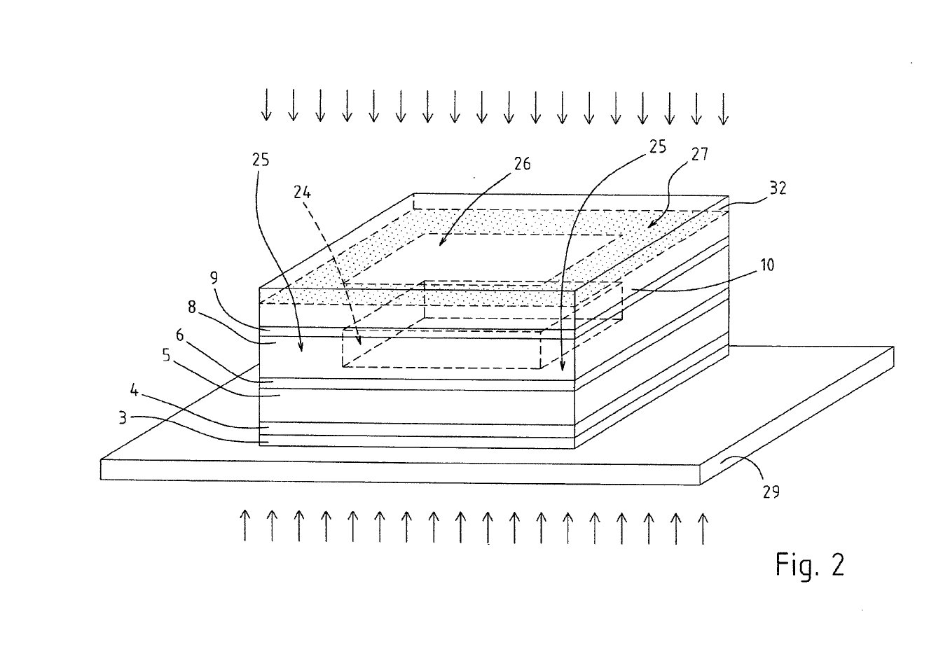

With reference to FIG. 2, the method for producing the plate 1 comprises the step of laying in succession on a flat support 29, made of UV-transparent material (preferably glass), the protective outer layer 3, the base layer 4, the first photopolymerisable polymer in a liquid state, the UV-proof stiffening layer 6, the second photopolymerisable polymer in a liquid state, the protective outer layer 9 and the protective film 10.

The method therefore envisages the application upon the protective film 10 of a flat plate 32 made of UV-transparent material, preferably glass.

Finally, the method foresees the simultaneous UV radiation of both sides of the plate 1 comprised between the flat support 29 and the plate 32.

In particular, the method envisages the radiation of both sides of the plate 1 for a time necessary to ensure complete polymerization of the first photopolymerisable polymer and complete polymerization of the frame 25 of the second photopolymerisable polymer. The portion 24 of the second layer 8 is instead not polymerized as it is protected by the UV-proof portion 26 of the protective film 10.

Preferably, the UV-ray exposure is performed with a special machine (not shown in the attached figures) comprising two UV-ray sources.

Generally, the exposure time to UV-rays is between about 0.5 and about 15 minutes depending on the thickness of the first layer 5 and the second layer 8 and the type of photopolymerisable polymer used.

Once the production of the plate 1 for producing stereotypes is done, then one proceeds with the actual production of the stereotype. The protective film 10 is removed and the lettertypes and the forms are formed in the non-polymerised portion 24 of the plate 1 by way of UV-ray exposure. After which the protective outer layer 9 is removed and the stereotype is subjected to a washing step for removing residual non-polymerised liquid polymer.

A not shown variant of the method comprises the steps of:
laying in succession upon a flat support, made of UV-transparent material (preferably glass), the protective outer layer, the base layer, the first photopolymerisable polymer in a liquid state and a stiffening layer;
radiating with UV-rays from above (i.e. directly radiating the stiffening layer) for a time necessary to completely polymerize the first photopolymerisable polymer (in this case, the stiffening layer 6 must necessarily be UV-transparent); a variant of the method envisages the radiation with UV-rays from below (i.e. directly radiating the flat support) for a time necessary to completely polymerize the first photopolymerisable polymer (in this case, the stiffening layer 6 can be either UV-transparent or UV-proof);
placing on the stiffening layer the second photopolymerisable polymer in a liquid state, the protective outer layer, the protective film having at least a non UV-transparent portion and a UV-transparent frame and a flat plate, made of UV-transparent material (preferably glass);
radiating with UV-rays from above (i.e. directly radiating the flat plate) for a time necessary to achieve complete polymerization of the second photopolymerisable polymer in the areas under the frame of the protective film.

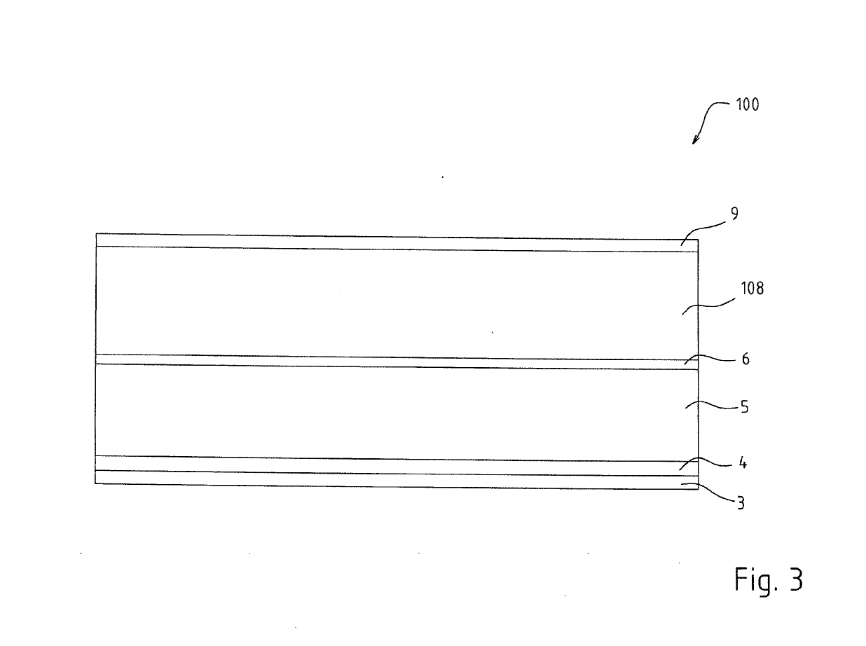

FIG. 3 shows a plate 100 for stereotypes according to a second embodiment.

In FIG. 3 the same reference numbers of FIG. 1 are maintained for indicating similar parts of the plates 1 and 100.

The plate 100 differs substantially from the plate 1 by the fact that the second layer 108 is completely polymerized and does not contain non-polymerised portions. Therefore, for forming the lettertypes and forms in the second layer 108 of the plate 100 it is necessary to use material removal techniques. The removal may be achieved by mechanical, chemical-physical ways or by sublimation by means of laser beams.

The characteristics of the first and second photopolymerisable polymer of the plate 100 are substantially the same as outlined in the description of the plate 1.

The method for producing the plate 100 does not provide, therefore, the use of a protective film 10, provided with a UV-transparent region and a non UV-transparent frame, for obtaining a partial polymerization of the photopolymerisable polymer.

A first method for producing the plate 100 envisages:
laying in succession upon a flat support made of UV-transparent material (not shown in FIG. 3), the protective outer layer 3, the base layer 4, the first photopolymerisable polymer in a liquid state, the stiffening layer 6, the second photopolymerisable polymer in the liquid state, the protective outer layer 9 and a flat plate (not shown in FIG. 3) made of UV-transparent material.
radiating simultaneously both sides of the plate 100 for a time necessary to achieve the complete polymerization of the first and second photopolymerisable polymers.

A second method for producing the plate 100 envisages two successive UV-ray radiation steps. More specifically this method envisages:
laying in succession upon a flat support made of UV-transparent material (not shown in FIG. 3), the protective outer layer 3, the base layer 4, the first photopolymerisable polymer in the liquid state, the stiffening layer 6;
radiating with UV-rays from above (i.e. directly radiating the stiffening layer 6) for a time necessary to achieve the complete polymerization of the first photopolymerisable polymer (in this case, the stiffening layer 6 must necessarily be UV-transparent), a variant of this step of the method consists of radiating with UV-rays from the bottom (i.e. radiating directly the flat support) for a time necessary to achieve the complete polymerization of the first photopolymerisable polymer (in this case, the stiffening layer 6 can be either UV-transparent or UV-proof);
laying upon the stiffening layer 6 the second photopolymerisable liquid polymer, the protective outer layer 9 and a flat plate (not shown in FIG. 3) made of UV-transparent material;
radiating with UV-rays from above (i.e. directly radiating the flat plate) for a time necessary to achieve the complete polymerization of the second photopolymerisable polymer (in this case, the stiffening layer 6 can be either UV-transparent or UV-proof); a variant of this method step envisages to radiate with UV-rays from below (i.e. radiating directly the flat support) for a time necessary to achieve the complete polymerization of the second photopolymerisable polymer (in this case, the stiffening layer 6 must necessarily be UV-transparent).

Advantageously, the plate 1, 100 according to the present invention is provided with a first layer 5 having certain mechanical properties and a second layer 8, 108 with mechanical properties differing from those of the first layer 5.

In particular, the second layer 8, 108 comprises a photopolymerisable polymer having a Shore A hardness degree different than the Shore A hardness degree of the second photopolymerisable polymer.

With the plate 1, 100 composed essentially of two layers of photopolymerisable polymer with different mechanical properties, a better quality printing is obtained with respect to the printing obtained from prior art plates.

In addition, the plate 1 according to the present invention can be manufactured in large scale and then be customized at the local print shop. In this way, the local print shop workers do not have to produce the plate by way of complicated and cumbersome procedures, but simply by drawing on the plate 1 the lettertypes or the forms requested by the customer.

Above all, the plate 1 must be exposed to a single exposure to UV-rays for the forming of lettertypes and forms. This results in a substantial saving for the print shop, which would need to introduce simple and less expensive machines than the double exposure machines previously used.

Moreover, thanks to the plate 1, the print shop would not necessitate the storage and handling of irritant or harmful chemicals usually used for the production of the plates.

Finally, the method for producing the plate 1, 100 is simple and allows to obtain high quality plates for stereotypes in short time.

It is also clear that to the plate 1, 100 for stereotypes and to the method for producing said plate, modifications and variations can be made without going beyond the scope of the appended claims.

1. Plate for producing printer stereotype comprising:
a first layer comprising a first photopolymerisable polymer, and
a second layer comprising a second photopolymerisable polymer.

2. Plate according to claim 1, wherein the first photopolymerisable polymer and the second photopolymerisable polymer have a different Shore A hardness degree.

3. Plate according to claim 1, wherein the first photopolymerisable polymer has a Shore A hardness degree comprised between 20 and 100.

4. Plate according to claim 1, wherein the second photopolymerisable polymer has a Shore A hardness degree comprised between 20 and 100.

5. Plate according to claim 1, wherein the first photopolymerisable polymer has a Shore A hardness degree greater than the Shore A hardness degree of the second photopolymerisable polymer.

6. Plate according to claim 1, comprising a stiffening layer arranged between the first layer and the second layer.

7. Plate according to claim 6, wherein the stiffening layer is made of a UV-proof material.

8. Plate according to claim 6, wherein the stiffening layer is made of a UV-transparent material.

9. Plate according to claim 1, wherein the first photopolymerisable polymer is completely polymerised and the second photopolymerisable polymer comprises at least a non-polymerised portion.

10. Plate according to claim 9, wherein the non-polymerised portion has a predefined shape.

11. Plate according to claim 1, wherein the first layer has a colour different from the colour of the second layer.

12. Method for manufacturing a plate for producing printer stereotype wherein the plate is made with a first layer comprising a first photopolymerisable polymer and with a second layer comprising a second photopolymerisable polymer.

13. Method according to claim 12, wherein the first photopolymerisable polymer and the second photopolymerisable polymer have a different Shore A hardness degree.

14. Method according to claim 12, wherein the first photopolymerisable polymer has a Shore A hardness degree comprised between 20 and 100.

15. Method according to claim 12, wherein the second photopolymerisable polymer has a Shore A hardness degree comprised between 20 and 100.

16. Method according to claim 12, wherein the first photopolymerisable polymer has a Shore A hardness degree greater than the Shore A hardness degree of the second photopolymerisable polymer.

17. Method according to claim 12, comprising the step of arranging a stiffening layer between the first layer and the second layer.

18. Method according to claim 12, comprising the step of polymerising the first layer by means of a UV-ray source.

19. Method according to claim 18, comprising the step of completely polymerising the second layer by means of a UV-ray source.

20. Method according to claim 18, comprising the step of partially polymerising the second layer by means of a UV-ray source, in such a way to obtain at least a non-polymerised portion.

21. Method according to claim 20, wherein the step of polymerising the first layer and the step of partially polymerising the second layer are carried out substantially simultaneously.

22. Method according to claim 20, wherein the step of partially polymerising the second layer comprises the step of arranging a protective film having at least a UV-proof region between a UV-ray source and the second layer and the step of irradiating the second layer by means of said UV-ray source.

23. Method according to claim 12, comprising the step of colouring the first layer and the second layer with different colours on the basis of the mechanical features of the first layer and of the second layer.
